(19) United States
(12) Patent Application Publication
(10) Pub. No.: US 2006/0035159 A1
(43) Pub. Date: Feb. 16, 2006

(54) Method of providing alignment marks, method of aligning a substrate, device manufacturing method, computer program, and device

(75) Inventors: Keith Frank Best, Prunedale, CA (US); Joseph J. Consolini, Costa Mesa, CA (US); Alexander Friz, San Jose, CA (US)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 10/914,604

(22) Filed: Aug. 10, 2004

(51) Int. Cl. G03F 9/00; G03C 5/00

(52) U.S. Cl. 430/22; 430/30

(57) ABSTRACT

In a method according to one embodiment, a first and second set of alignment marks are etched into a first side of the substrate. The first set of alignment marks are at location(s) such that they will appear in the object windows of front-to-backside alignment optics of a first lithographic apparatus, and the location(s) of the second set of alignment marks are selected according to an arrangement of alignment apparatus in another lithographic apparatus. The substrate is turned over, aligned using the first set of alignment marks and front-to-backside alignment optics and third and fourth set of alignment marks are etched into the substrate, directly opposite the second and first sets of alignment marks, respectively.

### FIELD OF THE INVENTION

The present invention relates to lithographic apparatus and device manufacturing methods using lithographic apparatus.

### BACKGROUND INFORMATION

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

The term “patterning device” used herein should be broadly interpreted as referring to means that can be used to impart a projection beam with a pattern in its cross-section such as to create a pattern in a target portion of the substrate. It should be noted that the pattern imparted to the projection beam may not exactly correspond to the desired pattern in the target portion of the substrate. Generally, the pattern imparted to the projection beam will correspond to a particular functional layer in a device being created in the target portion, such as an integrated circuit.

Patterning devices may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned. In each example of patterning device, the support structure may be a frame or table, for example, which may be fixed or movable as required and which may ensure that the patterning device is at a desired position, for example with respect to the projection system. Any use of the terms “reticle” or “mask” herein may be considered synonymous with the more general term “patterning device.”

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid or the use of a vacuum. Any use of the term “lens” herein may be considered as synonymous with the more general term “projection system”.

The illumination system may also encompass various types of optical components, including refractive, reflective, and catadioptric optical components for directing, shaping, or controlling the projection beam of radiation, and such components may also be referred to below, collectively or singularly, as a “lens”.

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein the substrate is immersed in a liquid having a relatively high refractive index, e.g. water, so as to fill a space between the final element of the projection system and the substrate. Immersion liquids may also be applied to other spaces in the lithographic apparatus, for example, between the mask and the first element of the projection system. Immersion techniques are well known in the art for increasing the numerical aperture of projection systems.

Before exposing the substrate, it may be desirable or necessary to correctly align it to ensure that the functional features are imaged on the correct position on the substrate. Conventionally this is shown using the apparatus shown in FIG. 2. Complementary alignment marks M₁, M₂ (details not shown in the accompanying Figures) and substrate marks P₁, P₂ are present on a mask and substrate respectively and an alignment system is used to detect alignment as shown in the accompanying FIG. 2. Examples of alignment systems are a conventional through-the-lens alignment system and also the alignment methods and apparatus described in co-pending European application numbers 02251440 and 02250235 and marks suitable for use therewith.

The marks are commonly on the front side of the substrate, but can also be on the back side of the substrate. Marks on the back side of the substrate are used, for example, when exposure is to take place on both sides of the substrate. This occurs particularly in the manufacture of micro electro mechanical systems (MEMS) or micro opto-electro mechanical systems (MIOEMS). When the substrate marks P₁ and P₂ (also referred to as “alignment marks” herein) are on the back surface of the substrate, they are re-imaged by front-to-back side alignment optics 22 at the side of substrate W to form an image Pᵢ as shown for P₂ in FIG. 2 of the accompanying drawings (P₁ would be re-imaged by another branch of the front-to-back side alignment optics). The front-to-back side alignment optics, together with the alignment system AS are used to determine the relative position of marks on the front side of the substrate to marks on the back side of the substrate. This enables functional features exposed on the front side of the substrate to be correctly lined up with functional features exposed on the back side of the substrate.

However, apparatus with such front-to-backside alignment capability may not include other features such as a tight overlay accuracy or be capable of fine geometry features. On the other hand, lithographic apparatus capable of fine geometry features and tight overlay accuracy may not include front-to-backside alignment apparatus. Using a conventional method, it is not therefore possible to combine other features such as both tight overlay accuracy with correctly aligned exposures on both sides of the substrate.

### SUMMARY

According to one embodiment, a method of providing alignment marks on a substrate comprises providing a first alignment mark on said first side of said substrate; providing a second alignment mark on said first side of said substrate at a known displacement from said first alignment mark; turning over said substrate; using front-to-backside alignment optics to align said substrate using said first alignment mark; and providing a third alignment mark on a second side of said substrate, wherein the location of said first alignment mark is such that it can be detected using front to backside alignment optics.

According to a further embodiment, there is provided a method of aligning a substrate comprising a method as described above.

According to a further embodiment, a device manufacturing method comprises providing a first alignment mark on said first side of a substrate; providing a second alignment mark on said first side of said substrate at a known displacement from said first alignment mark; turning over said substrate; using front-to-backside alignment optics to align said substrate using said first alignment mark; providing a third alignment mark on a second side of said substrate, wherein the location of said first alignment mark is such that it can be detected using front to backside alignment optics; moving said substrate to another apparatus; using said second alignment mark to align said substrate; projecting a patterned beam onto the substrate; turning over said substrate; using said third alignment mark to align said substrate; and projecting a patterned beam onto the substrate.

According to a further embodiment, there is provided a device manufactured according to a method described above.

A substrate according to a further embodiment is provided with a first alignment mark and a second alignment mark on a first side of the substrate and a third alignment mark on a second side of the substrate, wherein the first alignment mark is positioned on the substrate to be in the object order of front-to-backside alignment optics of a lithographic apparatus, the second and third alignment marks being positioned to be detectable by a different lithographic apparatus.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 schematically shows a use of front to backside alignment optics;

FIG. 3 shows first and second alignment marks on a first side of a substrate;

FIG. 4 depicts a substrate as shown in FIG. 3 being aligned using front-to-backside alignment marks;

FIG. 5 shows third and fourth alignment marks on a second side of a substrate as shown in FIG. 3; and

FIG. 6 depicts a section of a substrate with first, second, third and fourth substrate marks.

### DETAILED DESCRIPTION

Embodiments of the present invention may be applied to provide alignment marks to enable a substrate to be exposed by both apparatus with front-to-backside alignment capabilities and other lithographic apparatus.

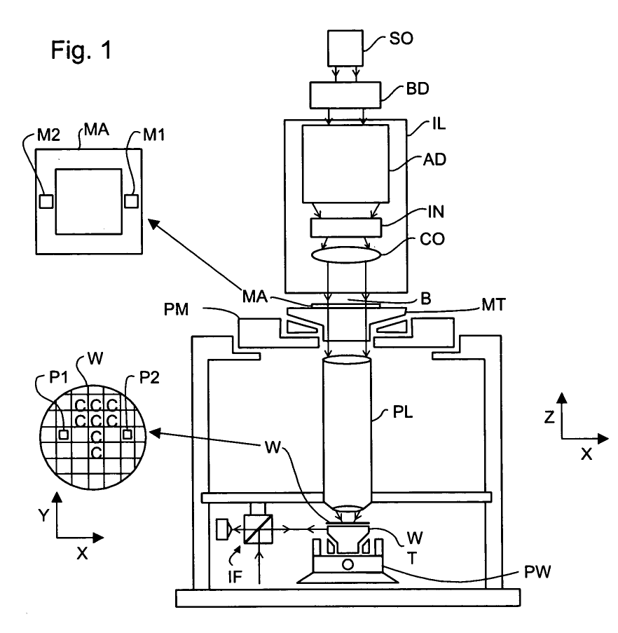

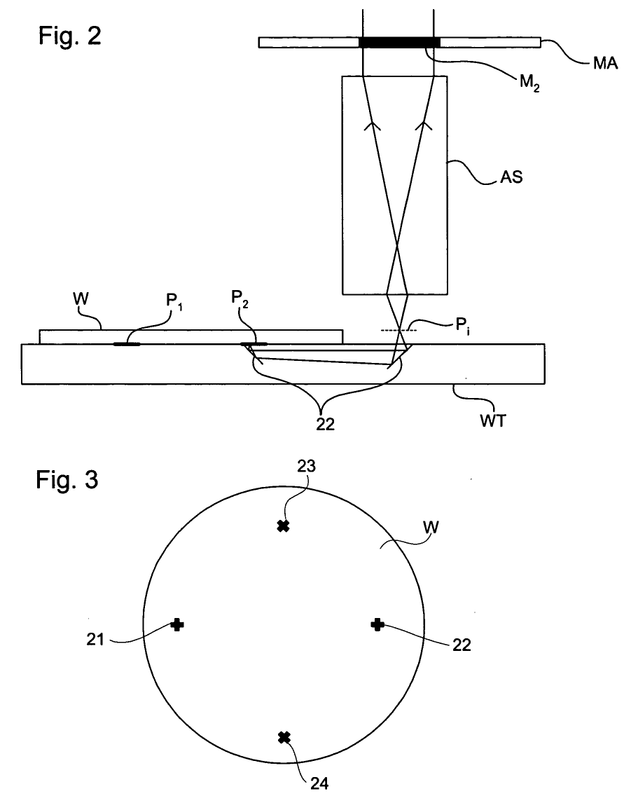

FIG. 1 schematically depicts a lithographic apparatus according to one embodiment of the invention. The apparatus comprises:

an illumination system (illuminator) IL configured to condition a radiation beam B (e.g. UV radiation).

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WT constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the support structure (e.g., mask table MT), and is patterned by the patterning device. Having traversed the mask MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:
1. In step mode, the mask table MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.
2. In scan mode, the mask table MT and the substrate table WT are scanned synchronously while a pattern imparted to the radiation beam is projected onto a target portion C (i.e. a single dynamic exposure). The velocity and direction of the substrate table WT relative to the mask table MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
3. In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

Prior to any device exposure, the substrate is etched with two first alignment marks 21, 22 as shown in FIG. 3. First alignment marks 21, 22 are located such that when the substrate is turned over the first alignment marks will appear in the object windows of front-to-backside alignment optics. Before turning the substrate over the substrate is also etched with a second set of alignment marks 23, 24. The second alignment marks are at a location appropriate for use with another lithographic apparatus (for example, an apparatus without front-to-backside alignment optics), i.e. the second alignment marks are at a location that would enable the other lithographic apparatus to detect the alignment marks. Furthermore, the shape of the second alignment mark may also be appropriate to the requirements of the other lithographic apparatus.

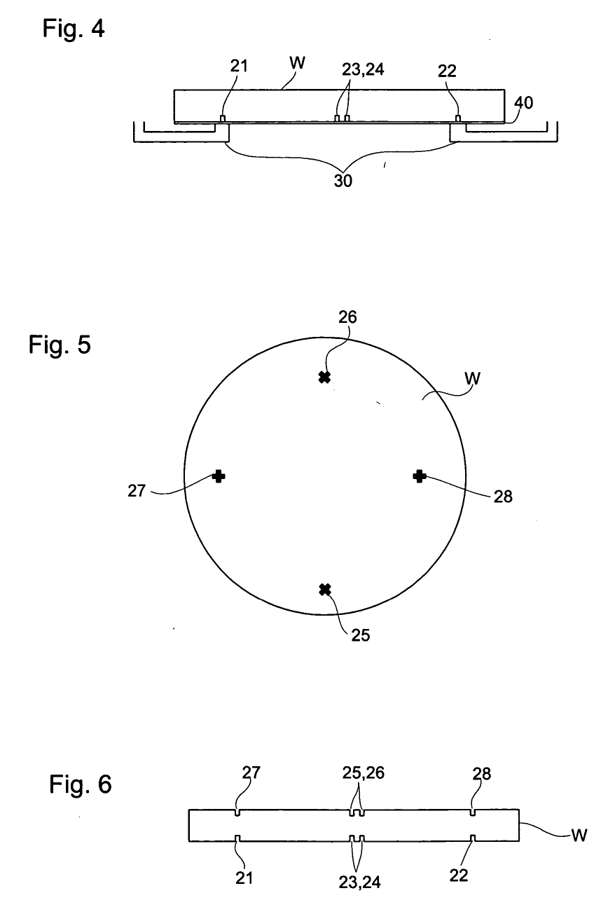

A layer of photoresist 40 is then applied to the first surface (i.e. the surface into which the first and second set of alignment marks, 21, 22, 23, 24 are etched) as a protective coating. As shown in FIG. 4 the substrate is then turned over so the first alignment marks 21, 22 lie in the object windows of the front-to-backside alignment optics 30. Through the front-to-backside alignment optics 30 alignment system AS detects the location of first alignment marks 21, 22 and thus the location of the substrate W. Third alignment marks 25, 26 which have the same shape as the second alignment marks are then etched into the second surface of the substrate at a location directly opposite to the second alignment marks 23, 24 as shown in FIGS. 5 and 6. Next, fourth alignment marks 27, 28 are etched into the substrate at locations directly opposite the first alignment marks 21, 22. Thus, if the substrate W is turned over the fourth alignment marks 27, 28 would be in the object windows of the front-to-backside alignment optics.

As the substrate has alignment marks corresponding to the lithographic apparatus used to expose the alignment marks, subsequent (device) exposures may be carried out using the same, or identical apparatus.

As the position of the second and third alignment marks 23, 24, 25, 26 need not be determined by the front-to-backside alignment optics, such position can be selected as appropriate for use with other lithographic apparatus. For example, if there was another lithographic apparatus which had other characteristics not available in the apparatus with front-to-backside alignment optics, the location of the second and third alignment marks could be governed by the desired location of alignment marks on the other lithographic apparatus. Additionally, the actual shape and nature of the second and third alignment marks 23, 24, 25, 26 may be selected as appropriate for use with this apparatus. Thus the second and third alignment marks 23, 24, 25, 26 enable the substrate to be exposed using other lithographic apparatus. Furthermore, even if the other apparatus does not have any front-to-backside alignment capability it is possible to correctly align exposures on the first side of the substrate to exposures on the second side of the substrate as the second alignment marks, 23, 24 and third alignment marks 25, 26 are a known displacement from each other. Thus, the alignment of the front and backside for exposure by any lithographic apparatus is now possible.

Although the second and third alignment marks are described as being opposite each other they need not be directly opposite each other, provided they are a known displacement from each other.

Although etching is commonly used to mark a substrate any method of marking a substrate is possible, e.g. fixing a mark to it and/or imprinting a mark upon it.

The mask used to expose the alignment marks should preferably be arranged in the center of the exposure beam to minimize any distortion.

Although each set of alignment marks described here comprises two alignment marks there may be one, three, four or even more alignment marks in each set.

In an application of an embodiment as disclosed herein, a substrate can thus be exposed by either lithographic apparatus with front-to-backside alignment capability, or by other lithographic apparatus. The second and third alignment marks are a known displacement from each other such that if the substrate is exposed by lithographic apparatus without front-to-backside alignment capability, the location of devices on the front side may still be related to the location of devices on the backside. Conveniently, the second and third alignment marks may be directly opposite each other on opposite sides of the substrate.

Preferably, the displacement between the first and second alignment marks is measured.

Such a method may further comprise providing a fourth alignment mark on the second side of the substrate, said fourth alignment mark being located such that it can be detected using front-to-backside alignment optics. An alignment mark can thus be detected through the front-to-backside alignment optics whichever side is facing down. The first and fourth alignment marks are preferably opposite each other.

To improve the accuracy of the readings, there may be a plurality of first, second, third or/and fourth alignment marks. First, second, third or/and fourth alignment marks may be commonly used.

The second and/or third alignment marks may be located at a position to be detected when the substrate is being exposed by another lithographic apparatus.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1. A method of providing alignment marks on a substrate, said method comprising:
providing a first alignment mark on a first side of said substrate, said first alignment mark being located such that it can be detected using front-to-backside alignment optics;
providing a second alignment mark on said first side of said substrate at a known displacement from said first alignment mark;
turning over said substrate;
using front-to-backside alignment optics and said first alignment mark to align said substrate; and
providing a third alignment mark on a second side of said substrate.

2. The method of providing alignment marks according to claim 1, said method comprising measuring the displacement between said first and said second alignment marks.

3. The method of providing alignment marks according to claim 1, wherein a displacement between said third alignment mark and said second alignment mark is known.

4. The method of providing alignment marks according to claim 3, wherein said second and third alignment marks are directly opposite each other on either side of the substrate.

5. The method of providing alignment marks according to claim 1, said method comprising providing a fourth alignment mark on said second side of said substrate, said fourth alignment mark being located such that it can be detected using front-to-backside alignment optics.

6. The method of providing alignment marks according to claim 5, wherein said substrate is provided with a plurality of fourth alignment marks.

7. The method of providing alignment marks according to claim 1, wherein said substrate is provided with a plurality of first alignment marks.

8. The method of providing alignment marks according to claim 1, wherein said substrate is provided with a plurality of second alignment marks.

9. The method of providing alignment marks according to claim 1, wherein said substrate is provided with a plurality of third alignment marks.

10. The method of providing alignment marks according to claim 1, wherein said aligning said substrate comprises aligning said substrate with respect to a reference position.

11. The method of providing alignment marks according to claim 1, wherein said first alignment mark is located such that it can be detected using the same front-to-backside alignment optics used to align said substrate.

12. The method of providing alignment marks according to claim 1, wherein said first alignment mark is located such that it can be detected using front-to-backside alignment optics different from the front-to-backside alignment optics used to align said substrate.

13. A method of aligning a substrate comprising the method according to claim 1.

14. A device manufacturing method, said method comprising:
providing a first alignment mark on a first side of a substrate, said first alignment mark being located such that it can be detected using front-to-backside alignment optics;
providing a second alignment mark on said first side of said substrate at a known displacement from said first alignment mark;
turning over said substrate at a first apparatus, said first apparatus having front-to-backside alignment optics;
using said first alignment mark and the front-to-backside alignment optics of the first apparatus to align said substrate;
providing a third alignment mark on a second side of said aligned substrate at the first apparatus;
moving said substrate to a second apparatus;
at the second apparatus, using said second alignment mark to align said substrate and projecting a patterned beam onto the aligned substrate;
at the second apparatus, turning over said substrate; and
at the second apparatus, using said third alignment mark to align said substrate and projecting a patterned beam onto the aligned substrate.

15. The device manufacturing method according to claim 14, wherein said first alignment mark is located such that it can be detected using the front-to-backside alignment optics of the first apparatus.

16. The device manufacturing method according to claim 14, wherein said first alignment mark is located such that it can be detected using front-to-backside alignment optics different from the front-to-backside alignment optics of the first apparatus.

17. A device manufactured according to the method of claim 14.

18. A substrate comprising:
a first alignment mark and a second alignment mark on a first side of said substrate, and
a third alignment mark on a second side of said substrate different than the first side,
wherein said first alignment mark is positioned on the substrate to be in an object window of front-to-backside alignment optics of a first lithographic apparatus, and
wherein said second and third alignment marks are positioned to be detectable by a second lithographic apparatus different than the first lithographic apparatus.

19. A method of applying alignment marks, said method comprising:
applying a first alignment mark to a first side of a substrate;
applying a second alignment mark to said first side of the substrate at a known displacement from said first alignment mark;
using front-to-backside alignment optics and said first alignment mark, aligning the substrate with respect to a reference position; and
applying a third alignment mark to a second side of the aligned substrate, said second side being substantially opposite to said first side.

20. The method of applying alignment marks according to claim 19, wherein at least one among said applying a first alignment mark, said applying a second alignment mark, and said applying a third alignment mark comprises projecting an image of the respective alignment mark toward the respective side of the substrate.

21. The method of applying alignment marks according to claim 19, wherein at least one among said applying a first alignment mark, said applying a second alignment mark, and said applying a third alignment mark comprises imprinting the respective alignment mark upon the respective side of the substrate.

22. The method of applying alignment marks according to claim 19, wherein at least one among said applying a first alignment mark, said applying a second alignment mark, and said applying a third alignment mark comprises fixing the respective alignment mark to the respective side of the substrate.

23. The method of applying alignment marks according to claim 19, wherein during said aligning the substrate with respect to a reference position, said first side of the substrate faces away from the reference position.

24. The method of applying alignment marks according to claim 19, wherein one of said second and third alignment marks is substantially directly above the other of said second and third alignment marks in a direction perpendicular to at least one of said first and second sides.

25. The method of applying alignment marks according to claim 19, said method comprising applying a fourth alignment mark to the second side of the substrate,
wherein one of said first and fourth alignment marks is substantially directly above the other of said first and fourth alignment marks in a direction perpendicular to at least one of said first and second sides.
